(19) United States
(12) Patent Application Publication
(10) Pub. No.: US 2020/0194701 A1
(43) Pub. Date: Jun. 18, 2020

(54) PHOTON MULTIPLIER FILM

(71) Applicant: Cambridge Enterprise Limited, Cambridge (GB)

(72) Inventors: Kiril Radkov Kirov, Trumpington - Cambridge (GB); Akshay Rao, Cambridge (GB); Neil Clement Greenham, Cambridge (GB); Tom Jellicoe, Biggleswade (GB); Marcus Boehm, Regensburg (DE)

(21) Appl. No.: 16/604,017

(22) PCT Filed: Apr. 10, 2018
(86) PCT No.: PCT/GB2018/050953

§ 371 Date: Oct. 9, 2019

(30) Foreign Application Priority Data
Apr. 11, 2017 (GB) 1705834.8

(51) Int. Cl. H01L 51/44; C09K 11/66; C09K 11/02; H01L 51/00; H01L 51/42

(52) U.S. Cl. CPC H01L 51/447; C09K 11/661; H01L 51/426; H01L 51/0094; C09K 11/025

(57) ABSTRACT

There is provided a ternary photon multiplier film. The photon multiplier film comprises an organic semiconductor material capable of multiple exciton generation and a luminescent material in a host material, wherein the bandgap of the luminescent material is selected such that the triplet excitons formed as a result from the multiple exciton generation in the organic semiconductor can be energy transferred into the luminescent material.

### FIELD OF INVENTION

The present invention relates, in general, to the composition of films containing organic semiconductors capable of multiple exciton generation. Particular compositions can be used in photovoltaic and other optoelectronic devices to give enhanced efficiencies.

### BACKGROUND OF THE INVENTION

Low band-gap solar cells like mono- and poly-crystalline Si represent more than 90% of the global solar photovoltaics market. The highest efficiency (26.3%) of mono-Si is close to the theoretical limit of 29.4%. Further efficiency improvement by reducing optical losses and charge recombination is difficult and costly to achieve. Therefore, in recent years a number of approaches have been explored to exceed the theoretical limit, such approaches include:

Mono-junctions based on carrier multiplication and singlet fission with maximum theoretical efficiency of ˜39%;

Tandem solar cells—tandems with theoretical efficiency in the range of 39-47% can be realised by different combinations of materials with and without carrier multiplication;

Spectral conversion—this group includes a range of spectral up- and down-conversion designs with or without photon multiplication.

Singlet fission has been actively researched for application in photovoltaics since around 2006 due to its potential to produce twice the photons or charges within a spectral range. It is a spin-allowed process in organic semiconductors in which a singlet exciton (S₁) formed upon light absorption is converted to two triplet excitons (T₁). For singlet fission to occur, the triplet exciton level must be close to half of the energy of the singlet exciton, e.g. S₁≅2*T₁. Since c-S₁, the most widely adopted solar technology, has a band gap E_{g} of 1.1 eV, singlet fission materials for use with it need to have a S₁ level of 2.3-2.6 eV (blue-green light absorption) and a T₁ level of 1.2-1.3 eV.

An example of singlet fission exploration for direct incorporation in the solar cell stack is disclosed in WO2014/001817.

Photovoltaic efficiency enhancement via singlet fission spectral conversion has also been investigated. The purely optical coupling between a photon multiplier film (PMF) and the underlying low band gap solar cell is advantageous because it puts fewer requirements on the singlet fission material functionality, e.g. no requirement to generate and conduct current. In addition the PMF can be developed independently of the well-optimised commercial cell production.

One example of a singlet fission PMF comprised of an organic sensitizing window layer deposited over a silicon cell is disclosed in WO 2014/052530. The organic sensitizing window layer consists of a singlet fission host material containing a phosphorescent emitter dopant, where the singlet fission host material has a triplet energy greater than or equal to the triplet energy of the phosphorescent emitter dopant. A singlet produced upon the absorption of one high energy photon by the singlet fission host undergoes fission into two triplets and each triplet is transferred to a separate phosphorescent emitter dopant. The process results in two near infrared photons being emitted from the phosphorescent emitter dopant which are subsequently absorbed into the adjacent silicon cell, producing two electron-hole pairs.

More recently two groups from the University of Cambridge and MIT have realised bilayer photon multiplier films based on acenes and lead chalchogenide quantum dots (QDs): US 2014/0224329 and WO2016/009203. The transfer of non-emissive triplet excitons to the infrared emissive QDs is novel and has been shown to occur via Dexter transfer. This transfer mechanism relies on orbital overlap between the excitation donor and the excitation acceptor. It is therefore expected to occur efficiently only on very short length scales (<1 nm). Indeed, it was found that the efficiency of triplet transfer from the SF material (SFM) to the QDs decreased from ˜90% to ˜10% when the length of the ligands attached to the QDs was increased from eight to eighteen C—C bonds (Thompson, N. J. et al., Nature Materials 13 (2014) 1039-1043).

### SUMMARY OF THE INVENTION

It is an object of the present invention to provide a photon multiplier film with improved efficiency. Further it is an object of the present invention to provide such a photon multiplier film in a form particularly suitable for fabrication on a commercial scale.

Accordingly, in a first aspect of the present invention there is provided a photon multiplier film with a ternary composition comprising an organic semiconductor material capable of multiple exciton generation and a luminescent material (emitter) dispersed in a host (or matrix) material, wherein the bandgap of the luminescent material is selected such that the triplet excitons formed in the organic semiconductor material as a result of multiple exciton generation can be energy transferred into the luminescent material.

Contrary to the expectation that the presence of the host material could disrupt the photon multiplication process, the performance of the photon multiplier film improves with increase of the host concentration. Such a result gave a surprising technical effect because:

at high host concentrations the packing of singlet fission material molecules is disrupted and the efficiency of singlet fission (as in the case of liquid solutions) is typically significantly reduced;

the dispersion of a small number of singlet fission molecules in a large number of host molecules or segments could reduce the diffusion length of singlet and triplet excitons;

due to the reported short-range nature of triplet energy transfer between the singlet fission material and the lead chalcogenide emitter used in some of the embodiments of this invention, it would be expected that the host material would act as a barrier to energy transfer.

Parasitic interactions between the host and the lead chalcogenide emitter used in some of the embodiments could lead to a decrease of the photoluminescence quantum yield of the emitter.

The present invention provides for a photon multiplier efficiency improvement of two orders of magnitude (245 times) relative to the performance of a system without a host.

As used herein, the term “organic semiconductor” means an organic material in which multiple exciton generation can take place. The organic semiconductor can be a small molecule, an oligomer, a homopolymer, a copolymer, a macromolecule, a dendrimer or an organometallic complex.

According to embodiments of the invention the organic semiconductor is preferably a singlet fission material. Singlet fission materials can be designed with a wide variation in the chemical structure and can include but are not limited to acenes, perylenes, rylenes, diketopyrrolopyroles, fluorene carotenoids, and benzofurans.

Preferably, the organic semiconductor capable of multiple exciton generation has a bandgap in the range 1.4 to 4.0 eV, preferably 2.0 to 3.0 eV, more preferably 2.3 to 2.6 eV.

The luminescent material may be an organic or an inorganic material to which excitations can be transferred from the organic semiconductor and emitted at a lower energy. The luminescent material may be an organic transition metal phosphorescent compound, a thermally delayed fluorescent material, a quantum dot (metal chalcogenide, Ill-V, II-VI, Si, Ge, graphene, graphene oxide), an emitter small molecule, oligomer, dendrimer, polymer, or macromolecule, a 2D material or a perovskite emitter.

Preferably, the triplet energy of the organic semiconductor is within 0.4 eV of the excited state of the luminescent material, preferably within 0.3 eV, more preferably within 0.2 eV.

Preferably, the bandgap of the luminescent material is in the range of 0.6 eV to 2.0 eV, preferably 0.8 eV to 1.6 eV, more preferably 0.9 eV to 1.4 eV.

According to embodiments of the present invention, the luminescent material comprises an inorganic semiconductor, preferably an inorganic colloidal nanoparticle. Preferably, the colloidal nanoparticle is an inorganic nanocrystal semiconductor. The inorganic nanocrystal semiconductor comprises nanocrystals comprising CdSe, CdS, ZnTe, ZnSe, PbS, PbSe, PbTe, HgS, HgSe, HgTe, HgCdTe, CdTe, CZTS, ZnS, CuInS₂, CuInGaSe, CuInGaS, Si, InAs, InP, InSb, SnS₂, CuS, Ge, and Fe₂S₃.

The quantum dots may be uniform in composition, but may also be of a graded or core/shell configuration. The grading or shell may be achieved using a variety of chemical elements and materials including but not limited to those listed above.

The inorganic luminescent nanocrystal may have a diameter of 50 nm or less, preferably 20 nm or less, preferably 10 nm or less, and more preferably 5 nm or less.

Preferably, the surface of the inorganic luminescent nanocrystal is passivated sterically or electrostatically to solubilise the nanocrystal in solvents compatible with the organic semiconductor and the host.

Generally, the surface of the inorganic nanoparticle can be passivated sterically with an organic compound of arbitrary length and shape. Typically the ligands are short hydrocarbon molecules directly attached to the inorganic nanoparticle surface. However, the ligand can be provided in excess and not all of it may be in direct contact with the inorganic nanoparticle. In this case the ligand itself may be a host. Alternatively, the ligand may be further polymerised or it may itself be an oligomer, a polymer, a macromolecule or a 3D network. In these cases, the ligand may also serve as a host.

According to embodiments of the present invention the surface of the inorganic luminescent nanocrystal is passivated using an organic hydrocarbon ligand.

As used herein, the term “host” comprises an organic material that modifies the morphology of the binary organic semiconductor/luminescent component to improve photon multiplication. The host may comprise a small molecule, an oligomer, a homopolymer, a copolymer, a macromolecule, a dendrimer or a three dimensional network of organic molecules.

The host can be chosen from a wide variety of chemical structure in order to ensure uniform dispersion of the organic semiconductor and of the luminescent material. According to embodiments of the present invention in order to disperse inorganic semiconductor nanoparticles the host may have functional groups providing hydrogen bonds including but not limited to —OH, —COOH, —SH, primary, secondary or ternary amine, phosphine, phosphonic, urethane, imide and silanol groups. The host may be of synthetic or natural origin.

According to embodiments of the current invention the host comprises a polymer. The host can be chosen from a wide variety of polymers and their derivatives including but not limited to polybutyrals, polyamides, polyurethanes, polythiols, polyesters, polymethacrylates, polystyrenes, epoxies, polycarbonates, polyolefins, EVAs, silicones. Macromolecules of natural origin that may be suitable as hosts include carbohydrates, proteins, nucleic acids, and lipids.

The organic host may or may not be covalently linked to the organic semiconductor and/or to the luminescent material.

In a second aspect of the present invention, there is provided a photon multiplier film comprising a ternary composition wherein the organic semiconductor capable of multiple exciton generation and the emitter material are present in mass concentrations x % and y % smaller than the mass concentration z % of the host material, e.g. z>x and z>y. x is defined to mean the ratio by mass of the organic semiconductor to all the components in the film. It is noted that in the case that the organic semiconductor is a polymer, or part of a polymer or 3D network, only the mass of the unit that provides the multiple exciton generation functionality is included in the calculation of x. Similarly, in the case that the emitter is an inorganic nanoparticle, only the mass of the particle and not its ligands is included in the definition of y. Here z is defined as the mass of the host to the total mass; and wherein the bandgap of the luminescent material is such that the triplet excitons formed as a result of multiple exciton generation in the organic semiconductor can be energy transferred into the luminescent material.

According to embodiments of the present invention varying the mass concentration of the host leads to tuning of the morphology of the photon multiplier film. High organic host concentrations lead to photon multiplier films with uniform dispersion of the organic semiconductor and of the luminescent material and enhanced photon multiplication. Preferably the concentration of the organic host z is in the range 15-99.7%, preferably in the range 30-99.7%, more preferably in the range 50-99.7% and very preferably in the range 80-99.7%.

According to embodiments of the present invention, lowering the concentration of the organic semiconductor leads to improved photon multiplication. Preferably, the concentration of the organic semiconductor x is <50%, preferably <20%, and more preferably <10%

According to embodiments of the present invention, the concentration of the emitter material y is <50%, preferably <20% and more preferably <10%.

In a third aspect of the present invention, the photon multiplier film is used in conjunction with another optoelectronic device or application including but not limited to solar cells, photodetectors, light-emitting diodes, field-effect transistors, displays, sensors and biological imaging.

Preferably, the photon multiplier film is used to enhance the efficiency of a solar cell. The cell may comprise crystalline silicon, amorphous silicon, copper indium gallium selenide (CIGS), germanium, CdTe, GaAs, InGaAs, InGaP, InP, quantum dot, metal oxide, organic polymer or small molecule or perovskite semiconductors such as organometal halide perovskite semiconductors and more specifically methylammonium lead iodide chloride (CH₃NH₃Pbl_{3-X}Cl_{X}).

### DESCRIPTION OF THE DRAWINGS

Embodiments of the invention will now be described, by way of example only, and with reference to the accompanying drawings of which:

FIG. 1 is a schematic diagram of a ternary photon multiplier film according to an embodiment of the invention;

FIG. 2 shows the photoluminescence (PL) and morphology of a TIPS-Tc:PbS-QD PMF useful for a technical understanding of an embodiment of the invention: a) PL spectrum measured in an integrating sphere using 532 nm monochromatic light excitation; b) AFM phase image;

FIG. 3 presents the morphology and photoluminescence of PVB:PbS QD films as a function of QD concentration useful for a technical understanding of an embodiment of the invention: a) AFM phase scans; b) normalised PL spectra measured in an integrating sphere using 405 nm excitation;

FIG. 4 shows the topography and phase AFM scans of PVB:TIPS-Tc:PbS-QD films with varying polyvinyl butyral (PVB) concentration in accordance with an embodiment of the invention;

FIG. 5 presents the photoluminescence quantum efficiency (PLQE) of PVB:TIPS-Tc:PbS PMFs in the 830-1500 nm wavelength as a function of PVB matrix concentration in accordance with an embodiment of the invention: i) monochromatic 532 nm excitation—red diamonds; ii) selective QD excitation with 785 nm monochromatic light—black triangle;

FIG. 6 is a graph of the absorption coefficients of TIPS-Tc and PbS QDs in accordance with an embodiment of the invention;

FIG. 7 is a graph of estimated fractions of 830-1500 nm emission from direct excitation of QDs and from excitation transfer to the QDs for the data of FIG. 5 in accordance with an embodiment of the invention; and

FIG. 8 is a graph of a photoluminescence spectrum of an optimised PVB:TIPS-Tc:PbS-QD PMF excited at 532 nm (a) and comparison of its QD PLQE with that of a binary PVB:PbS-QD film excited at 405 nm (b). The mass concentration of PbS in both films is 2%.

### DETAILED DESCRIPTION OF THE INVENTION

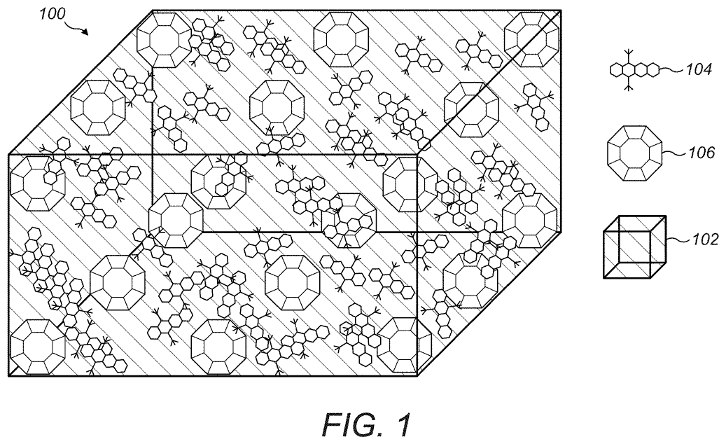

Referring to FIG. 1, a schematic of a photon multiplier film 100 according to an embodiment of the invention comprises a polyvinyl butyral (PVB) host material 102 in which bis(triisopropyl-silylethynyl) tetracene (TIPS-Tc) singlet fission material 104 and lead sulphide PbS quantum dots 106 are dispersed. The photon multiplier film 100 may be termed a Bulk Heterojunction photomultiplier film (BHJ-PMF), because of the presence of the singlet fission material 104 and quantum dots 106.

In FIG. 1, the quantum dots 106 are uniformly dispersed in the volume of the host material 102. The distance between quantum dot 106 centres is comparable with or no greater than the singlet diffusion length, which for organic materials is typically in the range 10-40 nm. In the present example, the distance between quantum dot 106 centres is 20 nm or 10-15 nm in some instances although not touching because touching or aggregation can hinder luminescence in the quantum dots 106. The singlet fission material 104 is also dispersed in the volume of the host material 102, but in such a way that:

the process of singlet fission is not disturbed throughout the volume of the photon multiplier film;

triplet diffusion is not inhibited—the singlet fission molecules are close enough throughout the host material 102 to allow diffusion of singlet and triplet excitons;

triplet transfer is possible—this requires some singlet fission materials to be positioned in close proximity (preferably <3 nm) to the quantum dots due to the short length scale over which the transfer takes place.

As described with reference to embodiments of the present invention, the process of photon multiplication in a singlet fission BHJ-PMF occurs via the following main steps:

light absorption (LA) by the singlet fission material and formation of singlet excited states;

triplet generation or yield (TY) via singlet fission;

triplet diffusion (TD) to the light emitting component (emitter dopant);

triplet transfer (TT) from the SF material to the emitter dopant;

light emission (LE) from the emitter dopant;

light out-coupling (LO) into the underlying low Eg solar cell.

The efficiency of photon multiplication is determined by the efficiency η of the main process steps above:

η_{PM}=η_{LA}*η_{TY}*η_{TD}*η_{TT}*η_{LE}*η_{LO}*100,(%) Eq.1

where η_{LA}, η_{TD}, η_{TT}, and η_{LO} can vary between 0 and 1, and η_{PM} and η_{TY} can vary between 0 and 2. The maximum efficiency of a PMF is therefore 200%.

According to a first aspect of the present invention, the BHJ-PMFs are developed without coupling to a solar cell, hence η_{LO} can be discarded. In addition, the PMFs are characterised using PLQE measurements in an integrating sphere. Since the PLQE calculation takes into account how much incident light has been absorbed by the PMF, η_{LA} can also be discarded. Eq. 1 is then simplified to:

[symbol]

_{PM}=η_{TY}*η_{TD}*η_{TT}* [symbol] _{QD}*100,%) Eq.2,

where we have replaced η_{PM} and η_{LE} with the experimentally measurable PLQE of the PMF ( [symbol] _{PM}) and of the QDs ( [symbol] _{QD}). The latter can be determined by selective QD excitation in the PMF or by measuring the PLQE of a binary MATRIX/QD film and assuming that [symbol] _{QD} changes little upon the addition of the SF material.

### Example 1

By way of technical background for the understanding of the present invention, Example 1 shows the performance of a binary BHJ-PMF based on TIPS-Tc and PbS QDs with Eg=1.15 eV (emission in the 830-1500 range) and a solution PLQE of 55%. The PbS QDs were synthesized using the method described in Zhang, J. et al. “Diffusion Controlled Synthesis of PbS and PbSe Quantum Dots with in Situ Halide Passivation for Quantum Dot Solar Cells”, ACS Nano 8 (2014) 614-622. The PMF was prepared by dissolving 150 mg of TIPS-Tc in 0.970 ml chloroform and adding 30 μl of a 50 mg/ml of PbS QD dispersion in chloroform. The binary TIPS-Tc:PbS film was formed on a PET substrate by doctor blading in air at a speed of 1 m/min and an air gap of 600 μm. The coated BHJ-PMF was encapsulated in an inert atmosphere between microscope cover glass using a fast curing two-part epoxy resin in order to prevent interaction with oxygen and moisture during subsequent characterisation.

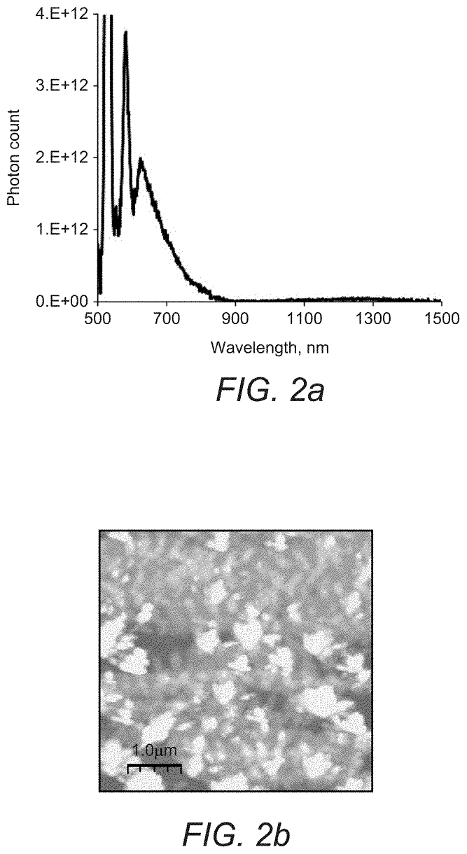

FIG. 2a illustrates a PL spectrum of the PMF obtained with 532 nm laser excitation. The PLQE in the range of QD emission is 0.08%. At this SF/QD ratio the QDs absorb only 0.03% of the total absorbed light. Therefore the photon multiplication process in this PMF is very inefficient, e.g. only ˜0.08% out of possible 199.94% is harvested.

FIG. 2b presents the morphology of the TIPS-Tc/PbS film measured using tapping mode AFM. The presence of domains several hundred nanometres in size is indicative of phase separation of the two components. Since the luminescent component is not uniformly distributed in the volume of the film it is to be expected that η_{TD} in this PMF is very low. It is also well known that QD aggregation leads to strong quenching of the emission. Hence, we can expect that [symbol] _{PbS} is also very low. Using Eq.2 we can reproduce the measured infrared PLQE using values for η_{TD} and [symbol] _{PbS} of 0.01 and 0.04, respectively.

### Example 2

By way of technical background for the understanding of the present invention, Example 2 demonstrates control over PbS QD aggregation by dispersing in a polyvinyl butyral (PVB) host material. The ternary PVB:PbS:CHCl₃ solution was prepared by first dissolving 150 mg of the polymer in ˜1 ml chloroform and then adding appropriate volumes of a 50 mg/ml PbS QD dispersion to achieve the desired QD concentration.

The solution preparation was performed in an inert atmosphere. The binary PMF films were prepared in air by doctor blading the solution on top of a PET film at a speed of 1 m/min with a blade/substrate gap of 950 μm.

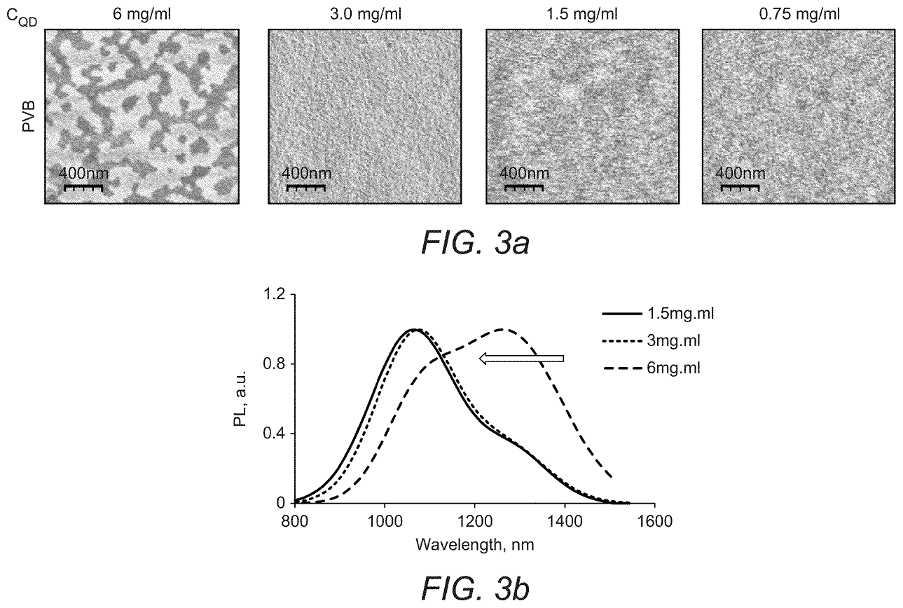

FIG. 3a shows the morphology of binary PVB:PbS films with varying PbS solution concentrations. The phase contrast in the film prepared from the solution with the highest PbS concentration of 6 mg/ml clearly demonstrates large-scale phase separation. However, the films prepared from solutions with a lower PbS concentration are essentially featureless. This indicates good dispersion of the QDs in the polymer matrix. The change in QD aggregation is also reflected in the disappearance of the red-shift in the PbS photoluminescence as shown in FIG. 3b. Despite minimising aggregation, the PLQE of the binary PVB:PbS films improves only slightly from 9.4 to 15.4%. This lack of significant improvement is most likely caused by the lack of a thick shell layer around the QD core and the occurrence of unwanted interactions with the functional groups of the surrounding polymeric matrix.

### Example 3

According to an embodiment of the invention, Example 3 shows how the morphology of a ternary PVB:TIPS-Tc:PbS film is tuned by changing the concentration of the host material, in the present example a polymer matrix.

The ternary films were prepared by weighing PVB and TIPS-Tc to a total mass of 150 mg and dissolving in 0.970 ml of chloroform. The amounts of the two components were varied to achieve the desired mass concentration of each component. The formed solutions were then topped up with 30 μl of a 50 mg/ml PbS QD dispersion in chloroform. The films were prepared as described in Example 2.

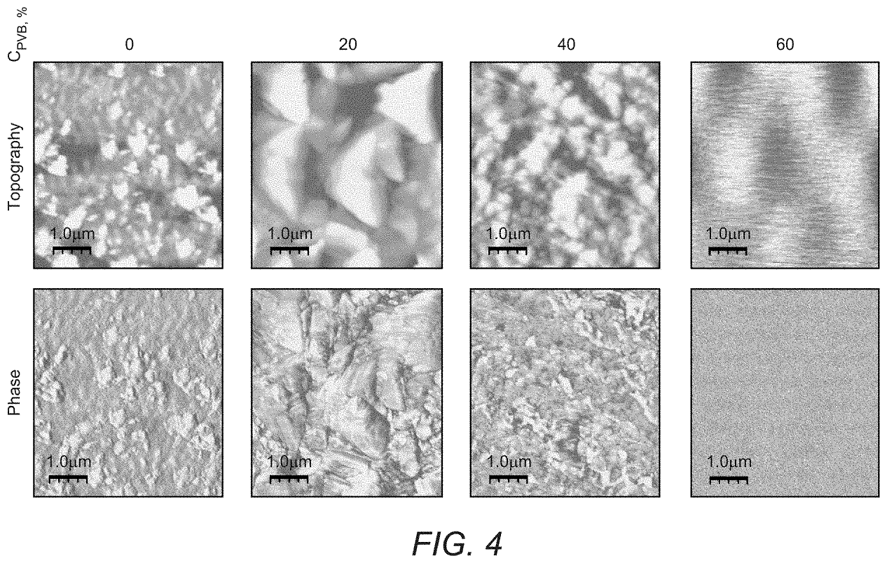

FIG. 4 shows the evolution of film morphology as a function of PVB matrix concentration. Films with low PVB concentration such as 0 to 40% have features ranging from several hundred nanometres to several micrometres in size. This confirms phase separation of the three components. Films with PVB concentration of 60% or more have a very low surface roughness (RMS_{1×1 μm}=0.46 nm) and lack phase contrast. Once again, this indicates good dispersion of both the SF material and the QDs in the polymer matrix.

### Example 4

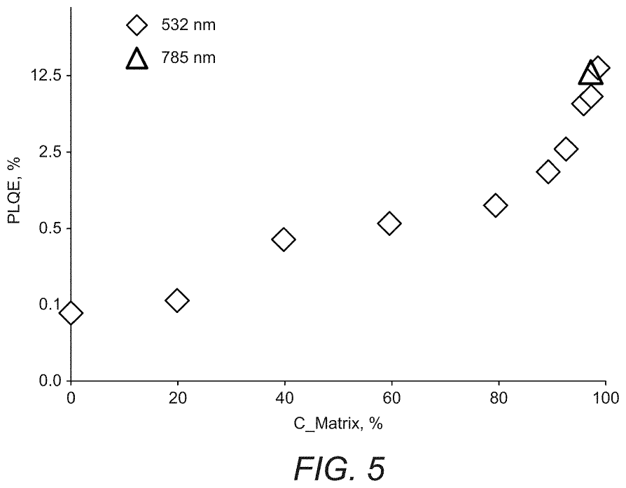

According to an embodiment of the invention, Example 4 shows that the performance of the PVB:TIPS-Tc:PbS PMF improves significantly as a function of polymer matrix concentration with reference to FIG. 5 and Table 1.

TABLE 1
Tabulated values of the data presented in FIG. 5.

| | | | | | | | | | | |
|---|---|---|---|---|---|---|---|---|---|---|
| Cₕₒₛₜ, mass % | 0 | 19.8 | 39.6 | 59.4 | 79.2 | 89.1 | 85.0 | 92.4 | 95.7 | 98.4 |
| PLQE_{830-1500 nm}, % | 0.08 | 0.11 | 0.40 | 0.56 | 0.82 | 1.67 | 2.68 | 7.05 | 8.12 | 15.00 |

The measured PLQE in the 830-1500 nm range of QD emission ( [symbol] _{PMF-QD}) changes from 0.08% for the binary TIPS-Tc:PbS-QD PMF to 15.0% for the ternary PVB:TIPS-Tc:PbS PMF with the highest PVB concentration of 98.3%. Since the PbS QDs absorb light at the excitation wavelength of 532 nm, the determined PLQE in the QD emission range can be expressed by Eq. 3:

[symbol]

_{PMF-QD}=A_{SFM}* [symbol] _{PM}+A_{QD}* [symbol] _{QD},(%) Eq. 3,

where A_{SFM} and A_{QD} represent the relative fractions of light absorbed by the SF material and by the QDs. The PLQE contribution from excitation transfer from the SF material to the QDs is then:

[symbol]

_{TRANSFER}=A_{SFM}* [symbol] _{PM}= [symbol] _{PMF-QD}−A_{QD}* [symbol] _{QD},(%) Eq. 4,

In the example of FIG. 5, the quantum efficiency of the PbS dots ( [symbol] _{QD}) in a PMF with 97% PVB concentration has been determined to be 13.6% by selective excitation with a 785 nm radiation. This value is close to the PLQE of binary PVB:PbS QD films of 15.4%.

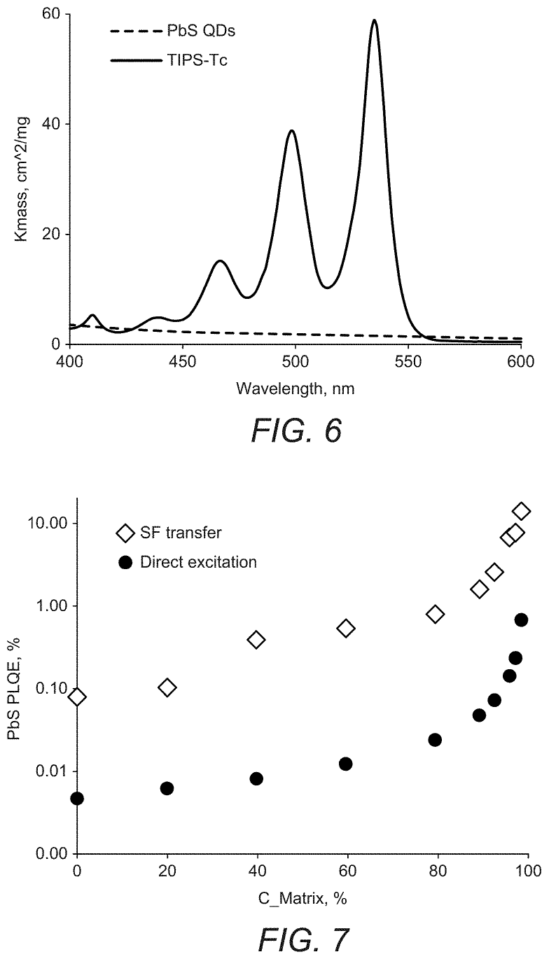

The two remaining unknowns in Eq. 4 (A_{SF} and A_{QD}) can be determined using Beer-Lambert's law. This requires knowledge of the absorption coefficients of the two light absorbing components. The mass absorption coefficients of TIPS-Tc and the PbS QDs are presented in FIG. 6. At the excitation wavelength of 532 nm, the absorption coefficient of TIPS-Tc is 35 times higher than that of the PbS QDs. Therefore, at this wavelength even for the lowest TIPS-Tc concentration of 0.7% the relative absorption of the SF material accounts for 95% of the total absorption.

The contributions to QD emission from direct QD excitation (A_{QD}* [symbol] _{QD}) and from SF/QD excitation transfer ( [symbol] _{TRANSFER}) calculated using Eq. 4 are presented in FIG. 7 and in Table 2. Even for the PMF with the highest PVB concentration (lowest SFM concentration), the PLQE from direct QD excitation is limited to 0.7%. The corresponding [symbol] _{TRANSFER} for this sample is 14.3%, e.g. comparable to [symbol] _{QD} in binary PVB/PbS-QD films and in ternary PMF films with low SFM concentration.

TABLE 2
Tabulated values of the data presented in FIG. 7. The PbS QD mass concentration is 1% for all samples.

| | | | | | | | | | | |
|---|---|---|---|---|---|---|---|---|---|---|
| C_{PVB}, | 0.0 | 19.8 | 39.6 | 59.4 | 79.2 | 89.1 | 92.4 | 95.7 | 97.0 | 98.3 |
| mass % | | | | | | | | | | |
| C_{TIPS-Tc}, | 99.0 | 79.2 | 59.4 | 39.6 | 19.8 | 9.9 | 6.6 | 3.3 | 2.0 | 0.7 |
| mass % | | | | | | | | | | |
| PbS PLQE - | 0.005 | 0.006 | 0.008 | 0.012 | 0.024 | 0.048 | 0.072 | 0.143 | 0.237 | 0.690 |
| direct | | | | | | | | | | |
| excitation, % | | | | | | | | | | |
| PbS PLQE - | 0.08 | 0.10 | 0.39 | 0.55 | 0.80 | 1.62 | 2.60 | 6.91 | 7.88 | 14.31 |
| transfer, % | | | | | | | | | | |

In principle, comparable [symbol] _{TRANSFER} and [symbol] _{QD} could be achieved by transferring purely singlet excitations from TIPS-Tc to the PbS QDs. However, taking into account the 35% PLQE in the singlet emission range (560-829 nm) and the 5% of incident photons lost to absorption in the PbS quantum dots, the maximum possible PLQE from singlet transfer is 9.2%. Therefore, the estimated [symbol] _{TRANSFER} of 14.3% for this sample can be achieved only if the process of photon multiplication takes place in it.

### Example 5

According to an embodiment of the invention, Example 5 presents the performance of an optimised ternary PFM to show that photon multiplication takes place very efficiently in it.

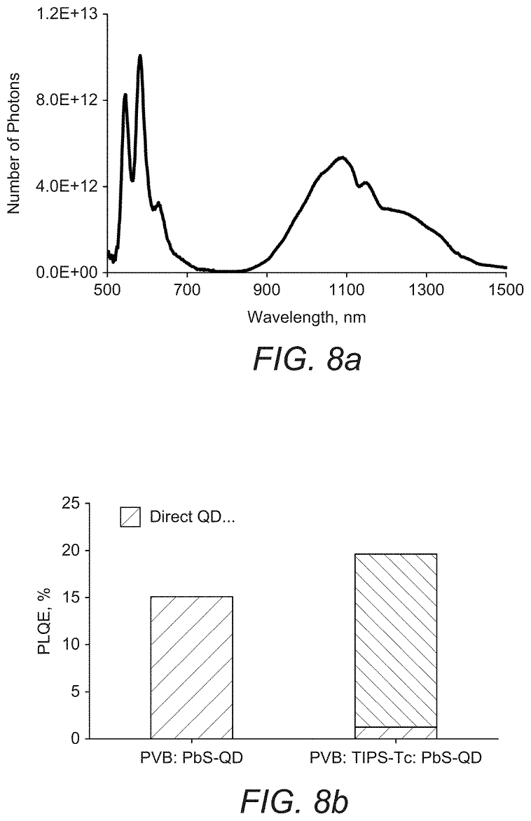

The film was prepared by doctor blading a PMF solution in chloroform with 149, 1 and 3 mg/ml concentrations of PVB, TIPS-Tc, and PbS QDs, respectively. The PMF has emissions both from the TIPS-Tc and from the QDs (FIG. 8a) with PLQE values of 21% and 19.6%, respectively.

Table 3 shows a detailed balance of the efficiency of the main processes calculated on the basis of Eq. 2-4. The PbS QDs contribute 8.6% to the total film absorption at the 532 nm excitation wavelength. Assuming [symbol] _{QD} in the PMF is the same as in a binary PVB/PbS-QD film (15.4%), the QD emission of the PMF from direct QD excitation is 1.3%. Therefore the residual PLQE of 18.3% in the QD emission range comes from transfer of excitons from the SFM to the QDs (FIG. 8b).

Since [symbol] _{TRANSFER}> [symbol] _{QD}, this demonstrates that photon multiplication does take place in this PMF. Using Eq. 2 we calculate that η_{TY}*η_{TD}*η_{TT} is 1.3 (or 130%). It should be noted, that due to losses from singlet emission ( [symbol] _{SFM}) and QD absorption (A_{QD}), the maximum triplet yield (η_{TY}) possible for this film decreases from 200% to ˜141%. Hence, the maximum value for η_{TY}*η_{TD}*η_{TT} is also 141%. The value of 130% estimated above shows that all three initial steps of the photon multiplication process occur almost quantitatively (92% relative efficiency) in this architecture. To stress this further, we show one possible set of η_{TY}, η_{TD} and η_{TT} (140.8%, 96% and 96%, respectively) that can yield the determined [symbol] _{TRANSFER} of 18.3% in the bottom part of Table 1.

The main performance limitation of the present ternary architecture comes from the low QD PLQE. Everything else being the same, increasing, [symbol] _{QD} to its maximum value (100%) would yield a PMF with a PLQE in the QD emission range ( [symbol] _{PMF}-QD) of 127% and a total PLQE ( [symbol] _{PMF}= [symbol] _{PMF-SFM}+ [symbol] _{PMF-QD}) of 148%.

TABLE 3
Analysis of the performance of an
optimised PVB: TIPS-Tc:PbS-QD PMF.

| | | |
|---|---|---|
| op_{PMF-QD 830-1500 nm} | | 19.6% |
| op_{SFM 560-829 nm} | | 21% |
| A_{SFM} | | 91.4% |
| A_{QD} | | 8.6% |
| op_{QD} | | 15.4% |
| A_{QD}*op_{QD} | | 1.3% |
| op_{TRANSFER} | | 18.3% |
| Max η_{TY}_{_{—}}_{MAX} | | 200% |
| | Losses | |
| | 2*A_{QD} | 17.2% |
| | 2* op_{SFM} | 42% |
| Max Residual η_{TY} | η_{TY}_{_{—}}_{MAX} − 2*A_{QD} − 2* op_{SFM} | 140.8% |
| op_{TRANSFER} | | 18.3% |
| A_{SFM} | | 91.4% |
| η_{TY} | | 140.8% |
| η_{TD} | | 96% |
| η_{TT} | | 96% |
| op_{QD} | | 15.4% |

1: A photon multiplier film comprising an organic semiconductor material capable of multiple exciton generation and a luminescent material in a host material, wherein the bandgap of the luminescent material is selected such that the triplet excitons formed as a result from the multiple exciton generation in the organic semiconductor can be energy transferred into the luminescent material.

2: The photon multiplier film as claimed in claim 1, wherein the organic semiconductor material and the luminescent material are present in mass concentrations x % and y %, wherein x and y are less than the mass concentration z % of the host material, such that z>x and z>y.

3: The photon multiplier film as claimed in claim 1, wherein the concentration of the host material by mass is greater than 15%.

4: The photon multiplier film as claimed in claim 3, wherein the concentration of the host material by mass is in the 15-99.7% range.

5: The photon multiplier film as claimed in claim 1, wherein the concentration of the organic semiconductor by mass is <50%.

6: The photon multiplier film as claimed in claim 1 where the concentration of the luminescent material by mass is <50%.

7: The photon multiplier film as claimed in claim 1, wherein the organic semiconductor is selected from a small molecule, an oligomer, a homopolymer, a copolymer, a dendrimer or an organometallic complex.

8: The photon multiplier film as claimed in claim 1, wherein the organic semiconductor is a singlet fission material.

9: The photon multiplier film as claimed in claim 8, wherein the singlet fission material is selected from an acene, a perylene, a rylene, a diketopyrrolopyrole, a fluorene, a carotenoid, a benzofuran.

10: The photon multiplier film as claimed in claim 1, wherein the organic semiconductor has a bandgap in the range 1.4 to 4.0 eV.

11: The photon multiplier film as claimed in claim 1, wherein the luminescent material is selected from one or more of an organic transition metal phosphorescent compound, a thermally delayed fluorescent organic compound, an inorganic semiconductor nanoparticle and a 2D or a perovskite material.

12. (canceled)

13: The photon multiplier film as claimed in claim 1, wherein the luminescent material is an inorganic nanocrystal semiconductor particle.

14: The e photon multiplier film as claimed in claim 12, wherein the luminescent material is selected from one or more nanocrystals comprising CdSe, CdS, ZnTe, ZnSe, PbS, PbSe, PbTe, HgS, HgSe, HgTe, HgCdTe, CdTe, CZTS, ZnS, CulnS₂, CuInGaSe, CuInGaS, Si, InAs, InP, InSb, SnS₂, CuS, Ge, and Fe₂S₃.

15. (canceled)

16: The photon multiplier film as claimed in claim 13, wherein the surface of the inorganic luminescent nanocrystal is passivated sterically or electrostatically to solubilise the nanocrystal in solvents compatible with the organic semiconductor and the host.

17-18. (canceled)

19: The photon multiplier film as claimed in claim 1, wherein the bandgap of the luminescent material is in the range of 0.6 eV to 2.0 eV.

20: The photon multiplier film as claimed in claim 1, wherein the triplet energy of the organic semiconductor is within 0.4 eV of the excited state of the luminescent material.

21: The photon multiplier film as claimed in claim 1, wherein the host material is an organic material selected from one or more of a small molecule, an oligomer, a homopolymer, a copolymer, a macromolecule, a dendrimer or a three dimensional network of organic molecules.

22: The photon multiplier film as claimed in claim 1, wherein the host material is selected from one or more of polybutyrals, polyamides, polyurethanes, polythiols, polyesters, polymethacrylates, epoxies, polycarbonates, polyolefins, EVAs, silicones, carbohydrates, proteins, nucleic acids and lipids.

23: The opto-electronic device comprising a photon multiplier film as claimed in claim 1, wherein the film is in optical communication with another optoelectronic device.

24: The opto-electronic device as claimed in claim 19, wherein the other optoelectronic device is one of a solar cell, photodetector, light-emitting diode, field-effect transistor, display, sensor or biological imaging device.
